(19) United States
(12) Patent Application Publication
(10) Pub. No.: US 2025/0294926 A1
(43) Pub. Date: Sep. 18, 2025

(54) LIGHT EMITTING ELEMENT

(71) Applicant: NICHIA CORPORATION, Anan-shi (JP)

(72) Inventors: Eiji MURAMOTO, Tokushima-shi (JP); Ryohei KOBAYASHI, Tokushima-shi (JP); Kosuke YOSHIOKA, Naruto-shi (JP)

(73) Assignee: NICHIA CORPORATION, Anan-shi (JP)

(21) Appl. No.: 19/077,653

(22) Filed: Mar. 12, 2025

(30) Foreign Application Priority Data
Mar. 18, 2024 (JP) 2024-042151

(51) Int. Cl. H10H 20/831; H10H 20/813; H10H 20/841

(52) U.S. Cl. CPC H10H 20/831; H10H 20/8132; H10H 20/841

(57) ABSTRACT

A light-emitting element includes a substrate; a conductive member disposed on the substrate; a first insulating layer disposed on the conductive member; a semiconductor structure comprising a first light-emitting unit and a second light-emitting unit on the first insulating layer, each comprising a first semiconductor layer, a second semiconductor layer, and a light-emitting layer disposed between the first semiconductor layer and the second semiconductor layer; first wiring electrically connected to the first semiconductor layer of the first light-emitting unit; second wiring electrically connected to the second semiconductor layer of the first light-emitting unit and the first semiconductor layer of the second light-emitting unit; third wiring electrically connected to the second semiconductor layer of the second light-emitting unit; and a pad electrode disposed above the substrate and spaced apart from the semiconductor structure in a plan view, the pad electrode being electrically connected to the first wiring.

### CROSS-REFERENCE TO RELATED APPLICATIONS

This application is based on and claims priority to Japanese Patent Application No. 2024-042151, filed on Mar. 18, 2024, the entire contents of which are incorporated herein by reference.

### FIELD

The present disclosure relates to a light-emitting element.

### BACKGROUND

Japanese Patent Publication No. 2015-501085 discloses a light-emitting element has been proposed in which two active regions connected in series to each other are provided on one substrate.

### SUMMARY

In a light-emitting element in the related art, unevenness in an emission intensity distribution is likely to occur.

An object of the present disclosure is to provide a light-emitting element that can reduce unevenness in an emission density distribution.

According to an aspect of the disclosed technology, a light-emitting element includes: a substrate having conductive member; a conductive member disposed on the substrate; a first insulating layer disposed on the conductive member; a semiconductor structure including a first light-emitting unit and a second light-emitting unit, the first light-emitting unit and the second light-emitting unit being spaced apart from each other on the first insulating layer, each of the first light-emitting unit and the second light-emitting unit including a first semiconductor layer of a first conductivity type, a second semiconductor layer of a second conductivity type, and a light-emitting layer disposed between the first semiconductor layer and the second semiconductor layer; first wiring electrically connected to the first semiconductor layer of the first light-emitting unit; second wiring electrically connected to the second semiconductor layer of the first light-emitting unit and the first semiconductor layer of the second light-emitting unit; third wiring electrically connected to the second semiconductor layer of the second light-emitting unit; and a pad electrode disposed above the substrate to be spaced apart from the semiconductor structure in a plan view, the pad electrode being electrically connected to the first wiring, wherein the second light-emitting unit is surrounded by the first light-emitting unit in a plan view, the first insulating layer includes a first opening overlapping the second light-emitting unit in a plan view, the third wiring is in contact with the conductive member through the first opening, and the first wiring and the second wiring are not in contact with the conductive member.

The present disclosure can provide a light-emitting element that can reduce unevenness in an emission density distribution.

### BRIEF DESCRIPTION OF DRAWINGS

FIG. 1 is a top view illustrating some of components of a light-emitting element according to an embodiment.

FIG. 2 is a cross-sectional view illustrating the light-emitting element according to the embodiment.

FIG. 3 is a cross-sectional view illustrating a light-emitting element according to a modified example of the embodiment.

### DETAILED DESCRIPTION

Hereinafter, an embodiment for carrying out the present disclosure is described with reference to the drawings. The following description is intended to embody technical concepts of the present disclosure, and but present invention is not limited to the described embodiments unless specifically stated.

In each drawing, members having identical functions may be denoted by the same reference characters. In view of the ease of explanation or understanding of the points, the embodiment may be illustrated separately for convenience, but the partial substitutions or combinations of the configurations illustrated in different embodiments and examples are possible. In embodiments described later, differences from the embodiment described earlier will be mainly described, and redundant descriptions of commonalities with the embodiment described earlier are sometimes omitted. The size, positional relationship, and other features of members illustrated in the drawings may be exaggerated to clarify explanation. To avoid excessive complication of the drawings, some elements may not be illustrated, or an end view illustrating only a cut surface may be used as a cross-sectional view. In addition, when viewed from any point, a +Z side is sometimes referred to as upper, an upper side, or above, and a −Z side may be referred to as lower, a lower side, or below. Viewing in a direction along the Z direction is referred to as “plan view.”

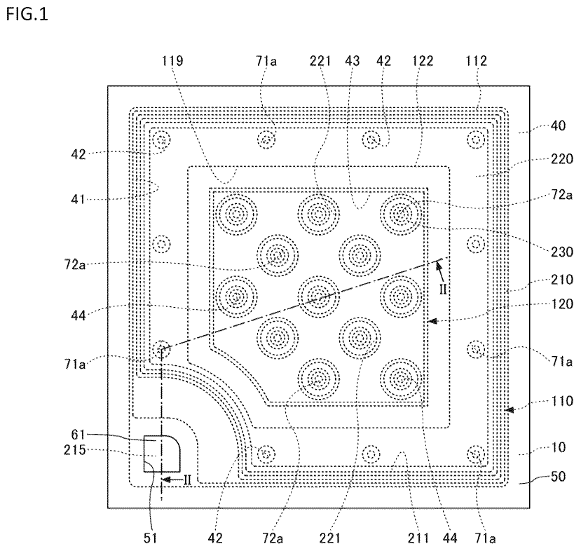

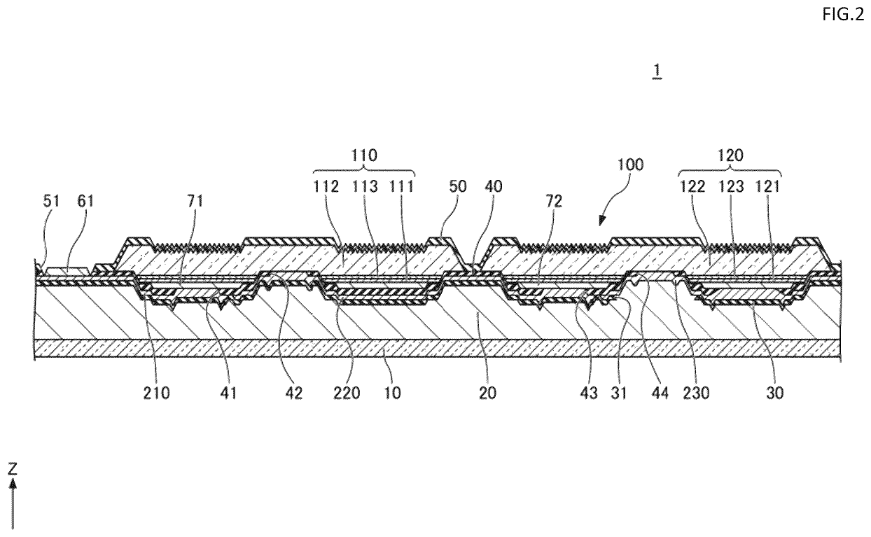

The embodiment relates to a light-emitting element. FIG. 1 is a top view illustrating a part of components of a light-emitting element according to the embodiment. FIG. 2 is a cross-sectional view illustrating the light-emitting element according to the embodiment. FIG. 2 corresponds to a cross-sectional view taken along line II-II in FIG. 1.

A light-emitting element 1 according to the embodiment includes a substrate 10, a conductive member 20, a first insulating layer 30, a second insulating layer 40, a third insulating layer 50, a pad electrode 61, light-reflective conductive layers 71 and 72, a semiconductor structure 100, first wiring 210, second wiring 220, and third wiring 230.

The substrate 10 is conductive. The shape of the substrate 10 is square in a plan view. When the shape of the substrate 10 is square in a plan view, the length of one side of the substrate 10 is in a range from 500 μm to 3000 μm, for example. In a plan view, the substrate 10 has vertices 11, 12, 13, and 14. The vertex 11 is a vertex on a −X side and a −Y side when the center of the substrate 10 is regarded as a point of origin. The vertex 12 is a vertex on a +X side and the −Y side when the center of the substrate 10 is regarded as the point of origin. The vertex 13 is a vertex on the +X side and a +Y side when the center of the substrate 10 is regarded as the point of origin. The vertex 14 is a vertex on the −X side and the +Y side when the center of the substrate 10 is regarded as the point of origin. For example, a silicon substrate having conductivity can be used for the substrate 10. The thickness of the substrate 10 is in a range from 100 μm to 1000 μm, for example.

As illustrated in FIG. 2, the conductive member 20 is disposed on the substrate 10. The conductive member 20 includes a metal layer of solder or the like. The thickness of the conductive member 20 is in a range from 3 μm to 10 μm, for example. The substrate 10 and the conductive member 20 are electrically connected to each other. The first insulating layer 30 is disposed on the conductive member 20. The first insulating layer 30contains, for example, at least one of silicon oxide, silicon nitride, and silicon oxynitride. The first wiring 210, the second wiring 220, and the third wiring 230 are disposed on the first insulating layer 30. The thickness of the first insulating layer 30 is in a range from 0.1 μm to 2 μm, for example.

As illustrated in FIG. 1, the first wiring 210 is disposed along an outer edge of the substrate 10. The outer shape of the first wiring 210 is substantially rectangular in a plan view. The first wiring 210 has an opening 211 having a substantially rectangular shape in a plan view. The first wiring 210 has a connection portion 215 in the vicinity of the vertex 11. The pad electrode 61 is connected to the connection portion 215.

As illustrated in FIG. 1, the second wiring 220 is disposed inside the opening 211 of the first wiring 210 in a plan view. In a plan view, the second wiring 220 has such an outer shape that one of the corner portions of the rectangular shape, which corresponds to a portion where the pad electrode 61 is disposed, is curved toward the center of the substrate 10. The second wiring 220 includes an opening 221. The second wiring 220 may include a plurality of openings 221. The shape of the opening 221 is circular in a plan view.

As illustrated in FIG. 1, the third wiring 230 is disposed inside the opening 221 of the second wiring 220 in a plan view. The shape of the third wiring 230 is circular in a plan view.

The material of the first wiring 210, the second wiring 220, and the third wiring 230 is metal. As the first wiring 210, the second wiring 220, and the third wiring 230, for example, a single-component metal such as Ag, Al, Ni, Rh, Au, Cu, Ti, Pt, Pd, Mo, Cr, Ru, and W, or an alloy containing these metals as main components can be preferably used. The material of the first wiring 210, the second wiring 220, and the third wiring 230 is, for example, an Al alloy. Each of the first wiring 210, the second wiring 220, and the third wiring 230 may have a single-layer structure including one of these metal layers, or a layered structure in which a plurality of layers are layered. The thickness of each of the first wiring 210, the second wiring 220, and the third wiring 230 is in a range from 0.3 μm to 3 μm, for example.

As illustrated in FIG. 2, the second insulating layer 40 is disposed on the first insulating layer 30 to cover the first wiring 210, the second wiring 220, and the third wiring 230. The second insulating layer 40 contains, for example, at least one of silicon oxide, silicon nitride, and silicon oxynitride. The second insulating layer 40 includes an opening 41, a plurality of openings 42 serving as second openings, an opening 43, and a plurality of openings 44. The openings 41, 42, 43, and 44 penetrate the second insulating layer 40. The thickness of the second insulating layer 40 is in a range from 0.1 μm to 2 μm, for example.

As illustrated in FIGS. 1 and 2, the opening 41 is disposed inside an outer edge of the first wiring 210 in a plan view. The openings 42 are disposed inside an outer edge of the second wiring 220 in a plan view. The shape of the opening 42 is circular in a plan view. When the shape of the opening 42 is circular in a plan view, the opening 42 has a diameter in a range from 2 μm to 20 μm. The plurality of openings 42 are disposed along the outer edge of the substrate 10 in a plan view. The opening 43 is spaced apart from the openings 42 and disposed inside the outer edge of the second wiring 220 in a plan view. The opening 44 is disposed inside an outer edge of the third wiring 230 in a plan view. The shape of the opening 44 is circular in a plan view. When the shape of the opening 44 is circular in a plan view, the opening 44 has a diameter in a range from 2 μm to 20 μm.

As illustrated in FIG. 2, the light-reflective conductive layer 71 is disposed on the second insulating layer 40 to be spaced apart from the opening 42 and to overlap a part of the first wiring 210 and a part of the second wiring 220 in cross-sectional view. The light-reflective conductive layer 71 is electrically connected to the first wiring 210 through the opening 41. The light-reflective conductive layer 71 has a plurality of openings 71a in a plan view. In a plan view, the opening 42 is disposed inside the opening 71a of the light-reflective conductive layer 71. The shape of the opening 71a of the light-reflective conductive layer 71 is circular in a plan view. The light-reflective conductive layer 72 is disposed on the second insulating layer 40 to be spaced apart from the opening 44 and to overlap a part of the second wiring 220 and a part of the third wiring 230 in a plan view. The light-reflective conductive layer 72 is electrically connected to the second wiring 220 through the opening 43. The light-reflective conductive layer 72 has a plurality of openings 72a in a plan view. In a plan view, the opening 42 is disposed inside the opening 72a of the light-reflective conductive layer 72. The shape of the opening 72a of the light-reflective conductive layer 72 is circular in a plan view. The material of the light-reflective conductive layers 71 and 72 is metal. As the light-reflective conductive layers 71 and 72, for example, a single-component metal such as Ag, Al, Ni, Ti, Pt, Ta, Ru, and Au, or an alloy containing these metals as main components can be preferably used. Each of the light-reflective conductive layers 71 and 72 may have a single-layer structure including one of these metal layers, or a layered structure in which a plurality of layers are layered. The thickness of the light-reflective conductive layer 71 is in a range from 0.05 μm to 1 μm, for example.

As illustrated in FIG. 2, the semiconductor structure 100 is disposed on the second insulating layer 40 and the light-reflective conductive layers 71 and 72. The semiconductor structure 100 includes a first light-emitting unit 110 and a second light-emitting unit 120. In a plan view, the first light-emitting unit 110 has a substantially rectangular shape including an opening 119. The first light-emitting unit 110 is disposed along the outer edge of the substrate 10 in a plan view. In a plan view, the second light-emitting unit 120 is disposed inside the opening 119 of the first light-emitting unit 110 and is surrounded by the first light-emitting unit 110. The thickness of the semiconductor structure 100 is in a range from 1 μm to 10 μm, for example.

The first light-emitting unit 110 includes a p-type semiconductor layer 111 as a first semiconductor layer, an n-type semiconductor layer 112 as a second semiconductor layer, and a light-emitting layer 113. The light-emitting layer 113 is disposed between the p-type semiconductor layer 111 and the n-type semiconductor layer 112. The p-type semiconductor layer 111 is disposed on the light-reflective conductive layer 71 and the second insulating layer 40 to be spaced apart from the opening 42 in a plan view. The light-emitting layer 113 is disposed on the p-type semiconductor layer 111. The light-reflective conductive layer 71 and the p-type semiconductor layer 111 are electrically connected to each other. The n-type semiconductor layer 112 is disposed on the second wiring 220, the light-emitting layer 113, and the second insulating layer 40. The outer shape of the n-type semiconductor layer 112 is substantially rectangular in a plan view. The n-type semiconductor layer 112 has an opening having a substantially rectangular shape in a plan view. The n-type semiconductor layer 112 is disposed along the outer edge of the substrate 10 in a plan view. An upper surface of the n-type semiconductor layer 112 located on a side opposite to the light-emitting layer 113 has a plurality of protruding portions. The protruding portions are disposed in a part of the n-type semiconductor layer 112 overlapping the light-emitting layer 113 in a plan view. The shape of the protruding portion of the n-type semiconductor layer 112 is, for example, triangular in cross-sectional view.

The second light-emitting unit 120 includes a p-type semiconductor layer 121 as a first semiconductor layer, an n-type semiconductor layer 122 as a second semiconductor layer, and a light-emitting layer 123. The light-emitting layer 123 is disposed between the p-type semiconductor layer 121 and the n-type semiconductor layer 122. The p-type semiconductor layer 121 is disposed on the light-reflective conductive layer 72 and the second insulating layer 40 to be spaced apart from the opening 44 in a plan view. The light-emitting layer 123 is disposed on the p-type semiconductor layer 121. The light-reflective conductive layer 72 and the p-type semiconductor layer 121 are electrically connected to each other. The n-type semiconductor layer 122 is disposed on the third wiring 230, the light-emitting layer 123, and the second insulating layer 40. The n-type semiconductor layer 122 is disposed inside the opening of the n-type semiconductor layer 112, and is surrounded by the n-type semiconductor layer 112 in a plan view. An upper surface of the n-type semiconductor layer 122 located on a side opposite to the light-emitting layer 123 has a plurality of protruding portions. The protruding portions are disposed in a part of the n-type semiconductor layer 122 overlapping the light-emitting layer 123 in a plan view. The shape of the protruding portion of the n-type semiconductor layer 122 is, for example, triangular in cross-sectional view.

The first light-emitting unit 110 and the second light-emitting unit 120 are spaced apart from each other. The first light-emitting unit 110 and the second light-emitting unit 120 are electrically connected to each other by conductive members such as the first wiring 210, the second wiring 220, and the third wiring 230.

For example, a nitride semiconductor can be used as the material of the p-type semiconductor layers 111 and 121, the material of the n-type semiconductor layers 112 and 122, and the material of the light-emitting layers 113 and 123. It is assumed that the “nitride semiconductor” includes semiconductors having any of compositions derived from a chemical formula expressed as In_{X}Al_{Y}Ga_{1-X-Y}N (0≤X, 0≤Y, X+Y<1) in which the composition ratios X and Y are changed within the respective ranges. In the above chemical formula, it is assumed that the “nitride semiconductor” includes a semiconductor further containing a group V element other than nitrogen (N), and a semiconductor further containing any of various elements added to control any of various physical properties such as a conductivity type. Each of the layers, which are the p-type semiconductor layers 111 and 121, the n-type semiconductor layers 112 and 122, and the light-emitting layers 113 and 123, may have a single-layer structure or a layered structure including a plurality of semiconductor layers having different compositions, thicknesses, and the like. In particular, each of the light-emitting layers 113 and 123 preferably has a single quantum well structure or a multiple quantum well structure in which thin semiconductor layers exhibiting a quantum effect are layered. Each of the n-type semiconductor layers 112 and 122 includes a semiconductor layer containing n-type impurities. The n-type impurity such as Si or Ge is used. Each of the p-type semiconductor layers 111 and 121 includes a semiconductor layer containing p-type impurities. The p-type impurity such as Mg or Zn is used. The peak wavelength of light emitted by the light-emitting layer 113 is the same as the peak wavelength of light emitted by the light-emitting layer 123. The peak wavelength of the light emitted by the light-emitting layers 113 and 123 is in a range from 210 nm to 580 nm, for example. The peak wavelength of the light emitted by the light-emitting layer 113 may be different from the peak wavelength of the light emitted by the light-emitting layer 123.

The first wiring 210 is electrically connected to the p-type semiconductor layer 111 of the first light-emitting unit 110 through the opening 41. The second wiring 220 is electrically connected to the n-type semiconductor layer 112 of the first light-emitting unit 110 through the opening 42. The second wiring 220 is also electrically connected to the p-type semiconductor layer 121 of the second light-emitting unit 120 through the opening 43. The third wiring 230 is electrically connected to the n-type semiconductor layer 122 of the second light-emitting unit 120 through the opening 44.

As illustrated in FIG. 2, the third insulating layer 50 covers the semiconductor structure 100 and the second insulating layer 40. The third insulating layer 50 contains, for example, at least one of silicon oxide, silicon nitride, and silicon oxynitride. A portion of the upper surface of the third insulating layer 50, overlapping the n-type semiconductor layers 112 and 122, has a shape corresponding to the shape of the protruding portions on the upper surface of each of the n-type semiconductor layers 112 and 122 in cross-sectional view. The layered body of the second insulating layer 40 and the third insulating layer 50 has an opening 51. The opening 51 penetrates the layered body of the second insulating layer 40 and the third insulating layer 50. The opening 51 extends to the connection portion 215 of the first wiring 210. The thickness of the third insulating layer 50 is in a range from 0.01 μm to 2 μm, for example.

The pad electrode 61 is disposed on the connection portion 215 inside the opening

51. The pad electrode 61 is electrically connected to the connection portion 215. That is, the pad electrode 61 is spaced apart from the semiconductor structure 100 in a plan view, and is electrically connected to the first wiring 210. The pad electrode 61 is spaced apart from the semiconductor structure 100 in a plan view, so that absorption of light from the semiconductor structure 100 by the pad electrode 61 can be reduced. As illustrated in FIG. 1, above the substrate 10, only the pad electrode 61 serving as an n-side pad electrode is disposed, while a pad electrode serving as a p-side pad electrode is not disposed, and instead, the substrate 10 is used as a p-side electrode. Therefore, as compared with the case in which the n-side pad electrode and the p-side pad electrode are disposed above the substrate 10, the area of the light-emitting unit can be increased, and high optical output can be easily obtained. As illustrated in FIG. 2, the first insulating layer 30 is disposed between the connection portion 215 and the conductive member 20. That is, the first insulating layer 30 is disposed between the pad electrode 61 and the conductive member 20.

As illustrated in FIG. 2, the first insulating layer 30 has an opening 31 as a first opening. The opening 31 penetrates the first insulating layer 30. The opening 31 overlaps the second light-emitting unit 120 in a plan view. The opening 31 further overlaps the third wiring 230 in a plan view. A part of the conductive member 20 is disposed inside the opening 31. The conductive member 20 is in contact with the third wiring 230. That is, the third wiring 230 is electrically connected to the conductive member 20 through the opening 31. On the other hand, the first wiring 210 and the second wiring 220 are not in contact with the conductive member 20.

In the present embodiment, the first insulating layer 30 has the opening 31 overlapping the second light-emitting unit 120 in a plan view. Thus, the third wiring 230 is electrically connected to the conductive member 20 through the opening 31. The conductive member 20 is electrically connected to the conductive substrate 10. That is, the third wiring 230 is electrically connected to the substrate 10 through the opening 31. When a current flows between the pad electrode 61 and the substrate 10, the first light-emitting unit 110 and the second light-emitting unit 120 emit light.

In the present embodiment, the second light-emitting unit 120 is surrounded by the first light-emitting unit 110 in a plan view. Therefore, the shape of a non-light-emitting unit between the first light-emitting unit 110 and the second light-emitting unit 120 in a plan view is a single closed curve shape having no end portion. The second light-emitting unit 120 is located on opposite sides of the first light-emitting unit 110 in any in-plane direction parallel to the upper surface of the substrate 10. Accordingly, the difference between the light emission intensity of the first light-emitting unit 110 and the light emission intensity of the second light-emitting unit 120 can be reduced. Thus, unevenness in the emission intensity distribution of the light-emitting element 1 can be reduced. For example, when the first light-emitting unit 110 and the second light-emitting unit 120 are disposed with a diagonal line of the substrate 10 used as a boundary, and when pad electrodes are respectively disposed at two diagonally positioned corner portions of the four corner portions of the substrate 10, then, the distance between the pad electrodes in a plan view is increased and the emission intensity distribution is likely to be biased to the light-emitting unit on either pad electrode side. In addition, heat generated in the semiconductor structure 100 is easily transmitted to the conductive member 20 and the substrate 10 through the opening 31, and heat dissipation properties can be improved.

Because the plurality of openings 42 are disposed along the outer edge of the substrate 10 in a plan view, a current easily flows uniformly through the n-type semiconductor layer 112, and unevenness in the emission intensity distribution can be more easily reduced. A plurality of openings may surround the second light-emitting unit 120 in a plan view. Also in this case, a current easily flows uniformly through the n-type semiconductor layer 112, and unevenness in the emission intensity distribution can be more easily reduced.

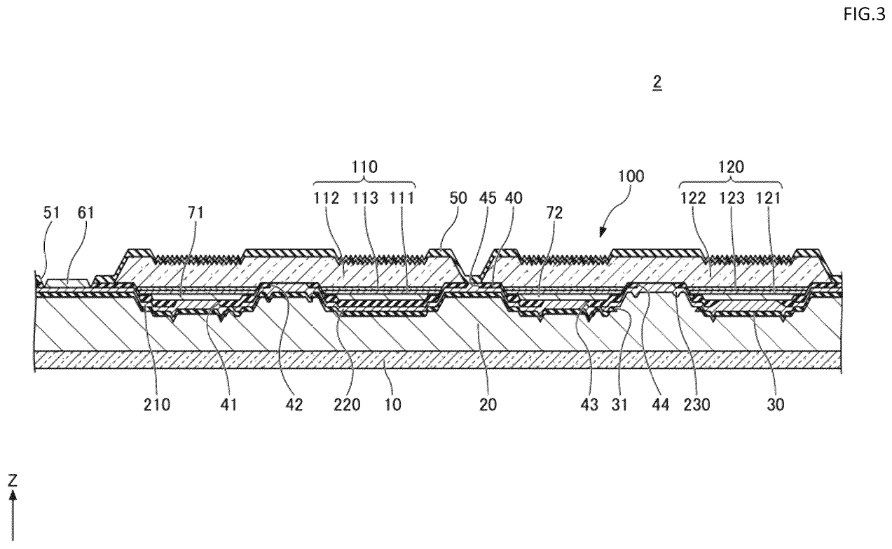

Subsequently, a modified example of the embodiment is described. FIG. 3 is a cross-sectional view illustrating a light-emitting element according to the modified example of the embodiment.

In a light-emitting element 2 according to the modified example of the embodiment, as illustrated in FIG. 3, the second insulating layer 40 includes an opening 45 as a third opening located between the first light-emitting unit 110 and the second light-emitting unit 120 in a plan view. For example, in a plan view, the opening 45 is surrounded by the first light-emitting unit 110, and the second light-emitting unit 120 is surrounded by the opening 45. A part of the second wiring 220 is disposed in the opening 45.

Other configurations of the modified example are basically the same as those of the above embodiment.

Effects similar to those of the embodiment can also be obtained by the modified example. Moreover, a part of light emitted by the light-emitting layers 113 and 123 is reflected by the second wiring 220 in the opening 45, and is thus emitted to the outside without being absorbed by the n-type semiconductor layers 112 and 122. This can improve light extraction efficiency.

Embodiments of the invention have been described in detail above. However, the invention is not limited to the above-described embodiments, and various modifications and substitutions can be made to the above-described embodiments without departing from the scope of the claims.

What is claimed is:

1. A light-emitting element comprising:
a substrate;
a conductive member disposed on the substrate;
a first insulating layer disposed on the conductive member;
a semiconductor structure comprising a first light-emitting unit and a second light-emitting unit that are spaced apart from each other on the first insulating layer, each of the first light-emitting unit and the second light-emitting unit comprising a first semiconductor layer of a first conductivity type, a second semiconductor layer of a second conductivity type, and a light-emitting layer disposed between the first semiconductor layer and the second semiconductor layer;
first wiring electrically connected to the first semiconductor layer of the first light-emitting unit;
second wiring electrically connected to the second semiconductor layer of the first light-emitting unit and the first semiconductor layer of the second light-emitting unit;
third wiring electrically connected to the second semiconductor layer of the second light-emitting unit; and
a pad electrode disposed above the substrate and spaced apart from the semiconductor structure in a plan view, the pad electrode being electrically connected to the first wiring, wherein:
the second light-emitting unit is surrounded by the first light-emitting unit in a plan view,
the first insulating layer comprises a first opening overlapping the second light-emitting unit in a plan view,
the third wiring is in contact with the conductive member through the first opening, and
the first wiring and the second wiring are not in contact with the conductive member.

2. The light-emitting element according to claim 1, further comprising:
a second insulating layer disposed between the first light-emitting unit and the second wiring and between the second light-emitting unit and the second wiring,
wherein the second insulating layer comprises a plurality of second openings extending to the second semiconductor layer of the first light-emitting unit,
the plurality of second openings surround the second light-emitting unit in a plan view, and
the second wiring is electrically connected to the second semiconductor layer of the first light-emitting unit through the plurality of second openings.

3. The light-emitting element according to claim 2, wherein:
the plurality of second openings are disposed along an outer edge of the substrate in a plan view.

4. The light-emitting element according to claim 3, wherein:
the second insulating layer comprises a third opening located between the first light-emitting unit and the second light-emitting unit in a plan view, and
a part of the second wiring is disposed in the third opening.

5. The light-emitting element according to claim 2, wherein:
the conductive member is disposed on an entirety of an upper surface of the substrate.

6. The light-emitting element according to claim 2, wherein:
the first insulating layer comprises a plurality of the first openings, and
the third wiring is disposed overlapping each of the first openings.

7. The light-emitting element according to claim 2, further comprising:
a first light-reflective conductive layer disposed on the second semiconductor layer of the first light-emitting unit, and a second light-reflective conductive layer disposed on the second semiconductor layer of the second light-emitting unit.

8. The light-emitting element according to claim 2, wherein:
an upper surface of the first semiconductor layer of the first light-emitting unit comprises a plurality of first protruding portions,
an upper surface of the first semiconductor layer of the second light-emitting unit comprises a plurality of second protruding portions,
the first protruding portions are disposed overlapping the light-emitting layer of the first light-emitting unit in a cross-sectional view, and
the second protruding portions are disposed overlapping the light-emitting layer of the second light-emitting unit in a cross-sectional view.

9. The light-emitting element according to claim 1, further comprising:
a second insulating layer disposed between the first light-emitting unit and the second wiring and between the second light-emitting unit and the second wiring, wherein:
the second insulating layer comprises a plurality of second openings extending to the second semiconductor layer of the first light-emitting unit,
the plurality of second openings are disposed along an outer edge of the substrate in a plan view, and
the second wiring is electrically connected to the second semiconductor layer of the first light-emitting unit through the plurality of second openings.

10. The light-emitting element according to claim 9, wherein:
the second insulating layer comprises a third opening located between the first light-emitting unit and the second light-emitting unit in a plan view, and
a part of the second wiring is disposed in the third opening.

11. The light-emitting element according to claim 1, wherein:
the conductive member is disposed on an entirety of an upper surface of the substrate.

12. The light-emitting element according to claim 1, wherein:
the first insulating layer comprises the plurality of first openings, and
the third wiring is disposed overlapping each of the first openings.

13. The light-emitting element according to claim 1, further comprising:
a first light-reflective conductive layer disposed on the second semiconductor layer of the first light-emitting unit, and a second light-reflective conductive layer disposed on the second semiconductor layer of the second light-emitting unit.

14. The light-emitting element according to claim 1, wherein:
an upper surface of the first semiconductor layer of the first light-emitting unit comprises a plurality of first protruding portions,
an upper surface of the first semiconductor layer of the second light-emitting unit comprises a plurality of second protruding portions,
the first protruding portions are disposed overlapping the light-emitting layer of the first light-emitting unit in a cross-sectional view, and
the second protruding portions are disposed overlapping the light-emitting layer of the second light-emitting unit in a cross-sectional view.

15. The light-emitting element according to claim 1, wherein:
the substrate comprises a silicon.

16. The light-emitting element according to claim 15, wherein:
a thickness of the substrate is in a range from 100 μm to 1000 μm.
